(19) United States
(12) Patent Application Publication
(10) Pub. No.: US 2025/0359124 A1
(43) Pub. Date: Nov. 20, 2025

(54) ANTENNA TUNING SWITCH STRUCTURE

(71) Applicant: WAVETEK MICROELECTRONICS CORPORATION, Hsinchu County (TW)

(72) Inventors: Hsien-Chin CHIU, Hsinchu County (TW); Barry Jia-Fu LIN, Hsinchu County (TW)

(21) Appl. No.: 19/208,606

(22) Filed: May 15, 2025

Related U.S. Application Data
(60) Provisional application No. 63/648,198, filed on May 16, 2024.

(30) Foreign Application Priority Data
Apr. 10, 2025 (TW) 114113648

(51) Int. Cl. H10D 30/47; H10D 62/85; H10D 64/64; H10D 64/66

(52) U.S. Cl. CPC H10D 30/471; H10D 62/8503; H10D 64/64; H10D 64/66

(57) ABSTRACT

Disclosed is an antenna tuning switch structure, which includes an epitaxial substrate, a gate structure, a source electrode and a drain electrode, which respectively arranged on the opposite sides of the gate structure. The epitaxial substrate includes a semiconductor substrate and a nitride heterostructure formed on the semiconductor substrate. There is a two-dimensional electron gas within the nitride heterostructure. The gate structure is disposed on the nitride heterostructure. One of the source electrode and the drain electrode is connected to an antenna, the other one of the source electrode and the drain electrode is connected to a tuning element, and the gate structure is configured to control an electrical connection between the tuning element and the antenna. Therefore, the antenna tuning switch structure can increase the breakdown voltage, and have low leakage current performance and high-power handling capability based on the two-dimensional electron gas, making it suitable for high-power environments.

### CROSS REFERENCE TO RELATED PRESENT DISCLOSURE

This application claims the priority benefit of U.S. Provisional Patent Application Ser. No. 63/648,198, filed on May 16, 2024; and claims the priority benefit of Taiwan Patent Application Ser. No. 114113648, filed on Apr. 10, 2025, each of which is hereby incorporated herein by reference in its entireties.

### TECHNICAL FIELD

The present disclosure relates to a switch structure, in particular to an antenna tuning switch structure.

### RELATED ART

Antennas are essential components in mobile communication systems with multiple working frequency bands. An antenna tuner is disposed between an antenna and a radio frequency (RF) front end, and the antenna tuner can provide adjustable impedance tuning through tuning elements to perform an impedance matching between a transceiver and the antenna, and adjust the resonant frequency of the antenna, thereby improving the transmission efficiency and quality of the signal.

The antenna tuner includes a plurality of switch circuits connected in parallel and a tuning element connected in series to each switch circuit. Existing switch circuit typically uses at least twenty-five silicon-on-insulator (SOI) connected in series to achieve a breakdown voltage of 100 volts (V), which is suitable for antenna tuners in high power environments (e.g., 34 dBm RF power). However, since at least twenty-five SOI transistors are connected in series to form a switch circuit, it is necessary to compensate for nonlinear changes caused by voltage changes, resulting in a problem of poor linear control.

Therefore, how to provide a solution to the above-mentioned technical problems is a problem that those skilled in the art need to solve.

### SUMMARY

Embodiments of the present disclosure provide an antenna tuning switch structure that can solve the problems of a large form factor and poor linear control of the existing antenna tuner since each switch circuit of the existing antenna tuner requires at least twenty-five SOI transistors to be connected in series to achieve the high breakdown voltage and needs to compensate for nonlinear changes caused by voltage changes.

To solve the above technical problems, the present disclosure is implemented as follows.

The present disclosure provides an antenna tuning switch structure, which includes an epitaxial substrate, a gate structure, a source electrode and a drain electrode. The epitaxial substrate includes a semiconductor substrate and a nitride heterostructure formed on the semiconductor substrate. There is a two-dimensional electron gas within the nitride heterostructure. The gate structure is disposed on the nitride heterostructure. The source electrode and the drain electrode are respectively arranged on opposite sides of the gate structure. When the source electrode is connected to an antenna, the drain electrode is connected to a tuning element. When the drain electrode is connected to an antenna, the source electrode is connected to a tuning element. The gate structure is configured to control an electrical connection between the tuning element and the antenna.

In the embodiments of the present disclosure, the antenna tuning switch structure improves the breakdown voltage through the wide bandgap characteristic of the nitride heterostructure, so that the switching circuit of the antenna tuner only needs a single antenna tuning switch structure or a small number of antenna tuning switch structures connected in series to meet the requirements of high-power antenna switches used in current communication systems. In addition, since a small number of antenna tuning switch structures are connected in series, there is no need to compensate for nonlinear changes caused by voltage changes, so the switch circuit of the antenna tuner using the antenna tuning switch structure has a miniaturized size and better linear control. Besides, the antenna tuning switch structure can have low leakage current performance and high-power handling capability based on the two-dimensional electron gas in the nitride heterostructure.

### BRIEF DESCRIPTION OF THE DRAWINGS

The accompanying drawings described herein are used to provide further understanding for the present disclosure, and constitute a part of the present disclosure. The exemplary embodiments of the present disclosure and their descriptions are used to explain the present disclosure, and do not constitute an improper limitation of the present disclosure. In the accompanying drawings:

FIG. 1 is a schematic diagram of an embodiment of a radio frequency circuit of an antenna tuner using an antenna tuning switch structure of the present disclosure;

FIG. 2 is a schematic diagram of a first embodiment of the antenna tuner of FIG. 1 connected to an antenna;

FIG. 3 is a schematic diagram of a second embodiment of the antenna tuner of FIG. 1 connected to an antenna; and

FIG. 4 is a schematic diagram of a third embodiment of the antenna tuner of FIG. 1 connected to an antenna.

### DETAILED DESCRIPTION OF THE EMBODIMENTS

The embodiments of the present disclosure will be described below with reference to the drawings. Directional terminology mentioned in the following embodiments, such as up, down, left, right, front, back, etc., is used with reference to the orientation of the figure(s) being described. As such, the directional terminology is used for purposes of illustration and not for limitation of the present disclosure. In the figures, the same reference numerals represent the same or similar elements or process flows.

It must be understood that the words “including”, “comprising” and the like used in this specification are used to indicate the existence of specific technical features, values, method steps, work processes, elements and/or components. However, it does not exclude that more technical features, values, method steps, work processes, elements, components, or any combination thereof can be added. In addition, the term “and/or” used in this specification includes any and all combinations of one or more of the associated listed items.

It must be understood that when an element is described as being “connected” or “coupled” to another element, it may be directly connected or coupled to another element, and intermediate elements therebetween may be present. In contrast, when an element is described as “directly connected” or “directly coupled” to another element, there is no intervening element therebetween.

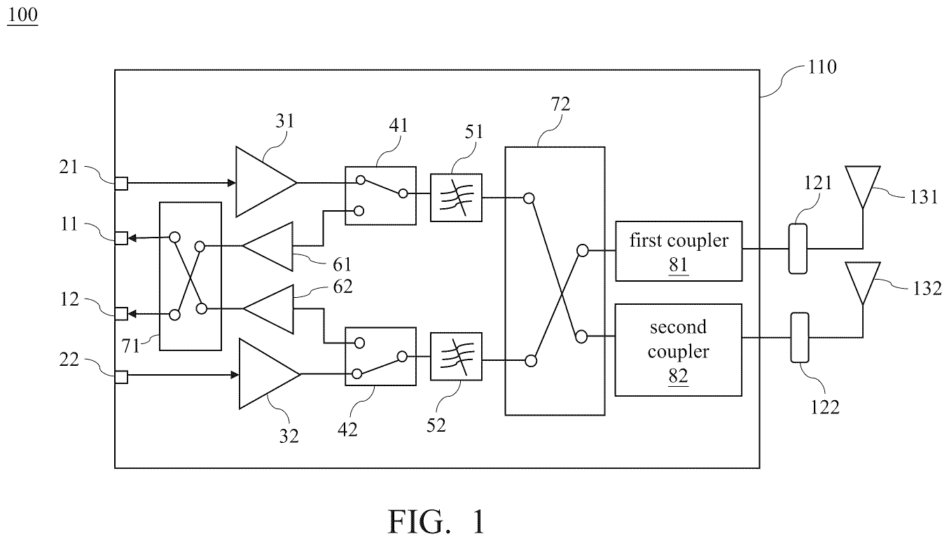

Please refer to FIG. 1, which is a schematic diagram of an embodiment of a radio frequency circuit of an antenna tuner using an antenna tuning switch structure of the present disclosure. As shown in FIG. 1, a radio frequency (RF) circuit 100 comprises a RF front end 110, an antenna tuner 121, an antenna tuner 122, an antenna 131, and an antenna 132. The RF front end 110 comprises a first signal receiving terminal 11, a first signal output terminal 21, a first power amplifier 31, a first single pole double throw (SPDT) switch 41, a first filter 51, a first low noise amplifier (LNA) 61, a first double pole double throw (DPDT) switch 71, a first coupler 81, a second signal receiving terminal 12, a second signal output terminal 22, a second power amplifier 32, a second SPDT switch 42, a second filter 52, a second LNA 62, a second DPDT switch 72 and a second coupler 82.

The antenna 131 and the antenna 132 may be a monopole antenna, an inverted F-shaped antenna (IFA), a loop antenna, a dipole antenna or a planar inverted-F antenna (PIFA), respectively. The first power amplifier 31 is configured to amplify a radio frequency signal with a first frequency band from the first signal output terminal 21, and the second power amplifier 32 is configured to amplify a radio frequency signal with a second frequency band from the second signal output terminal 22.

The first filter 51 is a bandpass filter configured to pass an RF signal in the first frequency band, and the second filter 52 is a bandpass filter configured to pass an RF signals in the second frequency band. The bandpass filter may be a filter configured to pass an RF signal (e.g., with less than 3 dB attenuation) within a frequency band. The first filter 51 and the second filter 52 may comprise an acoustic filter, an inductor-capacitor (LC) filter, a cavity filter, or a combination thereof. The acoustic filter comprises a surface acoustic wave (SAW) filter, a bulk acoustic wave (BAW) filter, and the like. The first frequency band may be a Long Term Evolution (LTE) frequency band, and the second frequency band may be a wireless local area network (WLAN) frequency band.

The first LNA 61 is configured to amplify the RF signal with the first frequency band that passes through the first filter 51 and output the amplified RF signal with the first frequency band. The second LNA 62 is configured to amplify the RF signal with the second frequency band that passes through the second filter 52 and output the amplified RF signal with the second frequency band. The first coupler 81 and the second coupler 82 may be, but are not limited to, directional couplers.

The antenna tuner 121 is connected to the antenna 131, and the antenna tuner 122 is connected to the antenna 132. The antenna 131 and the antenna 132 are configured to transmit and receive signals of different frequency bands. The antenna tuner 121 is configured to perform an impedance matching between the antenna 131 and the RF front end 110 and adjust the resonant frequency of the antenna 131. The antenna tuner 122 is configured to perform an impedance matching between the antenna 132 and the RF front end 110 and adjust the resonant frequency of the antenna 132.

After the first signal output terminal 21 receives the radio frequency signal with the first frequency band from the radio frequency transceiver (not shown), the radio frequency signal with the first frequency band is transmitted to the antenna 131 through the first power amplifier 31, the first SPDT switch 41, the first filter 51, the second DPDT switch 72, the first coupler 81 and the antenna tuner 121, so that the antenna 131 may convert the radio frequency signal with the first frequency band into an electromagnetic wave with the first frequency band and radiate the electromagnetic wave with the first frequency band. The antenna 131 may receive the electromagnetic wave with the first frequency band in the space. After the antenna 131 converts the electromagnetic wave with the first frequency band into the radio frequency signal with the first frequency band, the radio frequency signal with the first frequency band is transmitted to the radio frequency transceiver through the antenna tuner 121, the first coupler 81, the second DPDT switch 72, the first filter 51, the first SPDT switch 41, the first LNA 61, the first DPDT switch 71 and the first signal receiving terminal 11.

After the second signal output terminal 22 receives the RF signal with the second frequency band from the RF transceiver, the RF signal with the second frequency band is transmitted to the antenna 132 through the second power amplifier 32, the second SPDT switch 42, the second filter 52, the second DPDT switch 72, the second coupler 82 and the antenna tuner 122, so that the antenna 132 may convert the RF signal with the second frequency band into an electromagnetic wave with the second frequency band and radiate the electromagnetic wave with the second frequency band. The antenna 132 may receive the electromagnetic wave with the second frequency band in the space. After the antenna 132 converts the electromagnetic wave with the second frequency band into the RF signal with the second frequency band, the RF signal with the second frequency band is transmitted to the RF transceiver through the antenna tuner 122, the second coupler 82, the second DPDT switch 72, the second filter 52, the second SPDT switch 42, the second LNA 62, the first DPDT switch 71 and the second signal receiving terminal 12.

The antenna tuner 121, the antenna tuner 122, the first SPDT switch 41, the first DPDT switch 71, the second SPDT switch 42, and the second DPDT switch 72 may be controlled by the RF transceiver. The circuit architecture of the antenna tuner 121 and the circuit architecture of the antenna tuner 122 may be the same or different and may be adjusted and designed according to actual needs.

The radio frequency circuit 100 may be applied to electronic communication equipment, mobile equipment, clients, user equipment (UE), remote stations, access terminals, mobile terminals, user terminals, etc. The electronic communication equipment may comprise a laptop or desktop computer, a cellular phone, a smart phone, a wireless modem, an electronic reader, a tablet device, a game system, etc. The antenna tuner 121 may be a high-power antenna tuner, such as a fourth generation of mobile phone mobile communication technology standards (4G) antenna tuner or a 5th generation mobile communication technology (5G) antenna tuner for a smartphone, a Wi-Fi antenna tuner for a router, and an Internet of Things (IoT) RF front-end antenna tuner or a transfer switch for a wireless module, but this embodiment is not intended to limit the present disclosure.

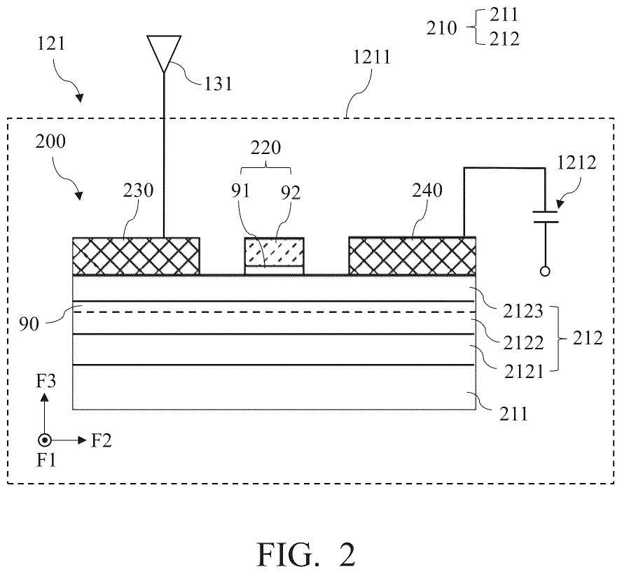

Please refer to FIG. 1 and FIG. 2, wherein FIG. 2 is a schematic diagram of a first embodiment of the antenna tuner of FIG. 1 connected to an antenna. The switch circuit 1211 of the antenna tuner 121 may adopt a single antenna tuning switch structure 200 (i.e., the antenna tuning switch structure 200 is applied to the antenna tuner 121), but this embodiment is not intended to limit the present disclosure. For example, the switch circuit 1211 of the antenna tuner 121 may use a plurality of antenna tuning switch structures 200 connected in series, and the number of antenna tuning switch structures 200 connected in series can be adjusted according to actual needs.

The antenna tuning switch structure 200 comprises an epitaxial substrate 210, a gate structure 220, a source electrode 230 and a drain electrode 240. The epitaxial substrate 210 comprises a semiconductor substrate 211 and a nitride heterostructure 212 formed on the semiconductor substrate 211. There is a two-dimensional electron gas 90 within the nitride heterostructure 212. The two-dimensional electron gas 90 refers to a phenomenon that an electron gas can move freely in a two-dimensional direction but is restricted in a third dimension, which can significantly improve the carrier/electron migration speed of the antenna tuning switch structure 200. The two-dimensional electron gas 90 is the conductive channel of the antenna tuning switch structure 200. The gate structure 220 is disposed on the nitride heterostructure 212, and the source electrode 230 and the drain electrode 240 are disposed on opposite sides of the gate structure 220. When the source electrode 230 is connected to the antenna 131, the drain electrode 240 is connected to the tuning element 1212. When the drain electrode 240 is connected to the antenna 131, the source electrode 230 is connected to the tuning element 1212. The gate structure 220 is configured to control an electrical connection between the tuning element 1212 and the antenna 131. Among them, the tuning element 1212 connected to the source electrode 230 or the drain electrode 240 may be a capacitor or an inductor, and the number of the tuning elements 1212 connected to the source electrode 230 or the drain electrode 240 may be one or more. When the number of the tuning elements 1212 connected to the source electrode 230 or the drain electrode 240 is plural, these tuning elements 1212 may be connected in series, in parallel, or partially in series and partially in parallel to generate different impedance values. The matching impedance value and the connection method of the tuning element 1212 may be selected according to actual needs.

It should be noted that, to facilitate explanation and help understand the structure of the antenna tuning switch structure 200 of the present disclosure, the drawings of the present disclosure show spatial directions such as a first direction F1, a second direction F2 and a third direction F3. The first direction F1 and the second direction F2 are perpendicular to each other and parallel to the surface of the epitaxial substrate 210, and the third direction F3 is perpendicular to the surface of the epitaxial substrate 210.

In this embodiment, the source electrode 230 may be connected to the antenna 131, the drain electrode 240 may be connected to the tuning element 1212, the tuning element 1212 may be a capacitor, and the source electrode 230 and the drain electrode 240 are respectively arranged on opposite sides of the gate structure 220 in the second direction F2; the antenna tuning switch structure 200 may be, but is not limited to, a high electron mobility transistor (HEMT), and the RF transceiver can be used to control the gate structure 220, but this embodiment is not used to limit the present disclosure.

The antenna tuning switch structure 200 improves the breakdown voltage through the wide bandgap characteristic of the nitride heterostructure 212, so that when the antenna tuning switch structure 200 is applied to the antenna tuner 121, the antenna tuning switch structure 200 can achieve a high breakdown voltage and meet the requirements of a high-power antenna switch. Compared with the existing antenna tuner that requires at least twenty-five SOI transistors to be connected in series, the antenna tuner 121 using the antenna tuning switch structure 200 does not need to compensate for nonlinear changes caused by voltage changes, so the antenna tuner 121 using the antenna tuning switch structure 200 has a miniaturized size and better linear control, and is suitable for operating systems with high output power.

In one embodiment, when the switch circuit 1211 of the antenna tuner 121 comprises M antenna tuning switch structures 200 connected in series and M is a positive integer greater than or equal to 2, the drain electrode 240 of the first antenna tuning switch structure 200 of the antenna tuning switch structures 200 connected in series may be connected to the tuning element 1212, and the source electrode 230 of the Mth antenna tuning switch structure 200 of the antenna tuning switch structures 200 connected in series may be connected to the antenna 131. If M is a positive integer greater than or equal to 3, the drain electrode 240 of the Kth antenna tuning switch structure 200 (1<K<M) of the antenna tuning switch structures 200 connected in series may be connected to the source electrode 230 of the antenna tuning switch structure 200 adjacent to one side of the Kth antenna tuning switch structure 200, and the source electrode 230 of the Kth antenna tuning switch structure 200 of the antenna tuning switch structures 200 connected in series may be connected to the drain electrode 240 of the antenna tuning switch structure 200 adjacent to the other side of the Kth antenna tuning switch structure 200. In other words, the drain electrode 240 of each of the antenna tuning switch structures 200 connected in series may be directly or indirectly connected to the tuning element 1212, and the source electrode 230 of each of the antenna tuning switch structures 200 connected in series may be directly or indirectly connected to the antenna 131.

In another embodiment, when the switch circuit 1211 of the antenna tuner 121 comprises M antenna tuning switch structures 200 connected in series and M is a positive integer greater than or equal to 2, the source electrode 230 of the first antenna tuning switch structure 200 of the antenna tuning switch structures 200 connected in series may be connected to the tuning element 1212, and the drain electrode 240 of the Mth antenna tuning switch structure 200 of the antenna tuning switch structures 200 connected in series may be connected to the antenna 131. If M is a positive integer greater than or equal to 3, the source electrode 230 of the Kth antenna tuning switch structure 200 (1<K<M) of the antenna tuning switch structures 200 connected in series may be connected to the drain electrode 240 of the antenna tuning switch structure 200 adjacent to one side of the Kth antenna tuning switch structure 200, and the drain electrode 240 of the Kth antenna tuning switch structure 200 of the antenna tuning switch structures 200 connected in series may be connected to the source electrode 230 of the antenna tuning switch structure 200 adjacent to the other side of the Kth antenna tuning switch structure 200. In other words, the source electrode 230 of each of the antenna tuning switch structures 200 connected in series may be directly or indirectly connected to the tuning element 1212, and the drain electrode 240 of each of the antenna tuning switch structures 200 connected in series may be directly or indirectly connected to the antenna 131.

In one embodiment, the semiconductor substrate 211 may be, but is not limited to, a substrate with a resistivity greater than 500 ohm-cm. Since the nitride heterostructure 212 is formed on the semiconductor substrate 211 with high resistivity, the isolation may be improved, thereby avoiding the loss of radio frequency signals. A material of the semiconductor substrate 211 may comprise but is not limited to floating zone silicon, gallium nitride, aluminum nitride, silicon carbide, sapphire or diamond, and the floating zone silicon is a silicon substrate grown using a float zone growing method.

In one embodiment, the nitride heterostructure 212 may comprise a buffer layer 2121 formed on the semiconductor substrate 211, a nitride channel layer 2122 formed on the buffer layer 2121, and a Schottky layer 2123 formed on the nitride channel layer 2122, and the two-dimensional electron gas 90 is formed in the nitride channel layer 2122 near an interface between the nitride channel layer 2122 and the Schottky layer 2123. The design of the buffer layer 2121 and the nitride channel layer 2122 provides better linear control. The buffer layer 2121, the nitride channel layer 2122 and the Schottky layer 2123 may all be formed by an epitaxial growth process, such as a metal-organic chemical vapor deposition (MOCVD) process, a hydride vapor phase epitaxy (HVPE) process, a molecular beam epitaxy (MBE) process, a combination of the above and other similar methods.

In one embodiment, the buffer layer 2121 may comprise an aluminum nitride/aluminum gallium nitride superlattice layer, an aluminum gallium nitride back barrier layer, an aluminum nitride back barrier layer and/or a grading/abrupt gallium nitride buffer layer, wherein the aluminum nitride/aluminum gallium nitride superlattice layer and the graded/mutated gallium nitride buffer layer may be used as stress buffer layers to enhance stress adjustment capability and reduce RF signal leakage through the semiconductor substrate 211; the graded/mutated gallium nitride buffer layer provides a gradient lattice constant; and the aluminum gallium nitride back barrier layer or the aluminum nitride back barrier layer may be used to prevent current collapse due to the surface polarization effect.

In one embodiment, a material of the nitride channel layer 2122 may comprise but is not limited to gallium nitride, aluminum gallium nitride, indium aluminum nitride, aluminum nitride, scandium gallium nitride, scandium aluminum nitride, boron nitride, aluminum indium gallium nitride and/or indium gallium nitride, and a material of the Schottky layer 2123 may comprise but is not limited to gallium nitride, aluminum gallium nitride, indium aluminum nitride, aluminum nitride, scandium gallium nitride, scandium aluminum nitride, boron nitride, aluminum indium gallium nitride and/or indium gallium nitride, wherein the material of the nitride channel layer 2122 is different from the material of the Schottky layer 2123. A potential dip is formed at the interface between the nitride channel layer 2122 and the Schottky layer 2123, and the free carriers are affected by the polarization field distribution and are gathered at the potential dip, so the two-dimensional electron gas 90 is formed in the nitride channel layer 2122 close to the Schottky layer 2123.

In one embodiment, the distance between the gate structure 220 and the source electrode 230 and the distance between the gate structure 220 and the drain electrode 240 may be the same or different.

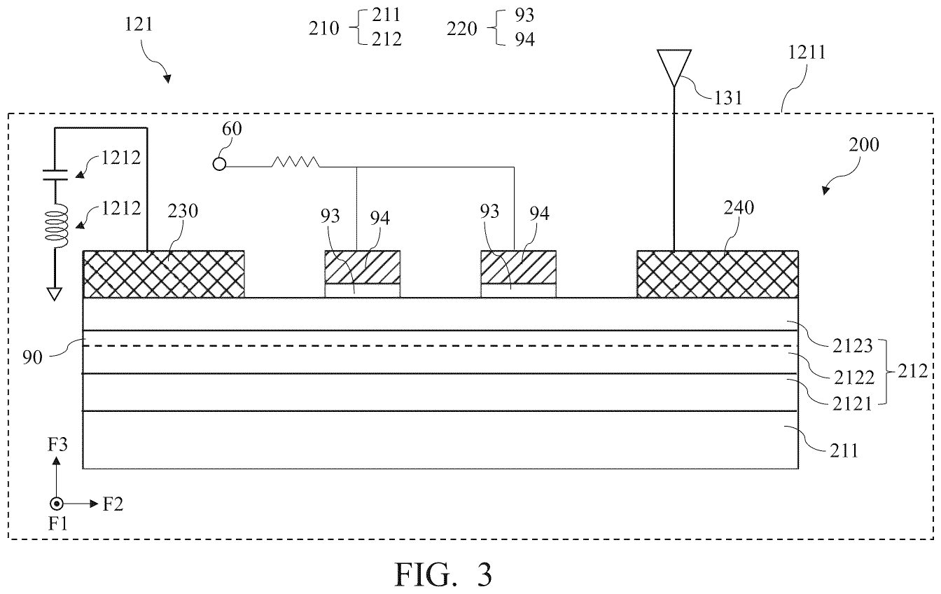

In one embodiment, the number of gate structures 220 may be only one (as shown in FIG. 2). In another embodiment, the number of gate structures 220 may be plural, and the source electrode 230 and the drain electrode 240 are respectively arranged on opposite sides of the plural gate structures 220 (as shown in FIG. 3, which is a schematic diagram of a second embodiment of the antenna tuner of FIG. 1 connected to an antenna), wherein the RF transceiver can simultaneously control the plural gate structures 220 through a single control terminal 60, and the breakdown voltage of the antenna tuning switch structure 200 may be increased by disposing the plural gate structures 220. In addition, in FIG. 3, the source electrode 230 may be connected to the tuning elements 1212, the number of the tuning elements 1212 may be two, the two tuning elements 1212 may be a capacitor and an inductor connected in series, and the drain electrode 240 may be connected to the antenna 131.

In one embodiment, the distance between any two adjacent gate structures 220 may be the same or different.

In one embodiment, the gate structure 220 may be a metal-insulator-semiconductor (MIS) structure (as shown in FIG. 2), wherein the metal-insulator-semiconductor structure comprises a dielectric layer 91 in contact with the nitride heterostructure 212 and a gate electrode 92 disposed on the dielectric layer 91, the material of the gate electrode 92 may comprise titanium, aluminum, nickel, gold, platinum, chromium, copper, iridium, titanium nitride, compounds thereof, composite layers thereof or alloys thereof, and the material of the dielectric layer 91 may comprise silicon nitride, silicon oxide, hafnium oxide or aluminum oxide, but this embodiment is not intended to limit the present disclosure. By designing the gate structure 220 as a MIS structure, the gate leakage current of the antenna tuning switch structure 200 may be reduced and the breakdown capability of the antenna tuning switch structure 200 may be improved. The dielectric layer 91 may be formed by an atomic layer deposition (ALD) process. The atomic layer deposition technology is suitable for the deposition of the dielectric layer 91 due to good uniformity, thickness control, low deposition temperature (heat treatment budget), and plasma-free deposition (which can avoid plasma-induced damage to the underlying epitaxial layer).

In another embodiment, the gate structure 220 may comprise a gallium nitride layer 93 in contact with the nitride heterostructure 212 and a gate electrode 94 disposed on the gallium nitride layer 93 (as shown in FIG. 3), and a Schottky contact may be formed between the gate electrode 94 and the gallium nitride layer 93, wherein the material of the gate electrode 94 may comprise titanium, aluminum, nickel, gold, platinum, chromium, copper, iridium, titanium nitride or compounds thereof. The gate electrode 94 contacts the gallium nitride layer 93, which generates a Schottky barrier at the contact surface (i.e., the so-called heterojunction), thereby improving the breakdown capability and anti-noise capability of the antenna tuning switch structure 200.

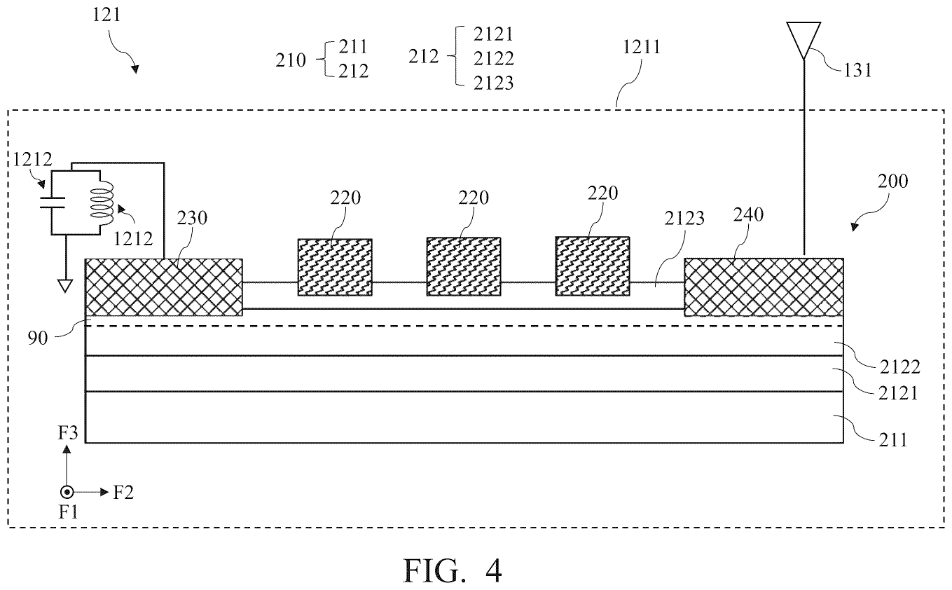

In yet another embodiment, the gate structure 220 is a P-type gallium nitride gate (as shown in FIG. 4, which is a schematic diagram of a third embodiment of the antenna tuner of FIG. 1 connected to an antenna), wherein the P-type gallium nitride gate comprises carbon-doped gallium nitride or magnesium-doped gallium nitride. In addition, the P-type gallium nitride gate is used to deplete the charge carriers generated in the underlying nitride channel layer 2122, so that the antenna tuning switch structure 200 is switched to be in a normally-off state. Besides, the P-type gallium nitride gate can be formed by an epitaxial growth process, such as a metal-organic chemical vapor deposition process, a molecular beam epitaxy process and a hydride vapor phase epitaxy process, and a photolithography process is used to define the pattern of the P-type gallium nitride gate. Moreover, in FIG. 4, the source electrode 230 may be connected to the tuning elements 1212, the number of the tuning elements 1212 may be two, the two tuning elements 1212 may be a capacitor and an inductor connected in parallel, and the drain electrode 240 may be connected to the antenna 131.

In one embodiment, the gate structure 220, the source electrode 230, and the drain electrode 240 directly contact the nitride heterostructure 212. Specifically, when the epitaxial substrate 210 comprises the semiconductor substrate 211, the buffer layer 2121, the nitride channel layer 2122 and the Schottky layer 2123 stacked in sequence, the gate structure 220, the source electrode 230 and the drain electrode 240 directly contact the Schottky layer 2123 (as shown in FIG. 2 and FIG. 3).

In another embodiment, the gate structure 220, the source electrode 230 and the drain electrode 240 not only directly contact the nitride heterostructure 212, but also extend into the nitride heterostructure 212 (i.e., in the opposite direction of the third direction F3). For example, when the epitaxial substrate 210 comprises the semiconductor substrate 211, the buffer layer 2121, the nitride channel layer 2122 and the Schottky layer 2123 stacked in sequence, the gate structure 220, the source electrode 230 and the drain electrode 240 may not only directly contact the Schottky layer 2123, but may also penetrate into the Schottky layer 2123 and/or the nitride channel layer 2122. The source electrode 230 and the drain electrode 240 may even directly contact the two-dimensional electron gas 90 (as shown in FIG. 4). Since the source electrode 230 and the drain electrode 240 extend into the nitride heterostructure 212 respectively, the source electrode 230 and the drain electrode 240 have a larger contact area with the nitride heterostructure 212 respectively. The larger contact area may result in the antenna tuning switch structure 200 having a lower contact resistance, thereby resulting in a better performance of the antenna tuning switch structure 200 during operation of the antenna tuning switch structure 200.

In one embodiment, the source electrode 230 and the drain electrode 240 may form ohmic contacts with the nitride heterostructure 212 respectively. The source electrode 230 and the drain electrode 240 may comprise a conductive material respectively, wherein the conductive material may comprise titanium, aluminum, nickel, silver, gold, platinum, chromium, copper, iridium, titanium nitride and tungsten, compounds thereof, composite layers thereof or alloys thereof, but are not limited thereto. In addition, the source electrode 230 and the drain electrode 240 may also be stacked layers that are in ohmic contact with the epitaxial substrate 210, such as Ti/Al, Ti/Al/Ti/TiN, Ti/Al/Ti/Au and Ti/Al/Ni/Au, but not limited thereto.

In summary, the antenna tuning switch structure improves the breakdown voltage through the wide bandgap characteristic of the nitride heterostructure, so that the switching circuit of the antenna tuner only needs a single antenna tuning switch structure or a small number of antenna tuning switch structures connected in series to meet the requirements of high-power antenna switches. In addition, since a small number of antenna tuning switch structures are connected in series, there is no need to compensate for nonlinear changes caused by voltage changes, so the switching circuit of the antenna tuner using the antenna tuning switch structure has a miniaturized size and better linear control and is suitable for high output power operating systems. Besides, the antenna tuning switch structure can have low leakage current performance and high-power handling capability based on the two-dimensional electron gas in the nitride heterostructure. Additionally, the nitride heterostructure is formed on the semiconductor substrate with high resistivity (i.e., the resistivity greater than 500 ohm-cm) to improve isolation and thus avoid RF signal loss. Furthermore, the breakdown voltage of the antenna tuning switch structure can be increased by disposing a plurality of gate structures. Moreover, by designing the gate structure as a MIS structure, the gate leakage current can be reduced and the breakdown capability of the antenna tuning switch structure can be improved.

While the present disclosure is disclosed in the foregoing embodiments, it should be noted that these descriptions are not intended to limit the present disclosure. On the contrary, the present disclosure covers modifications and equivalent arrangements obvious to those skilled in the art. Therefore, the scope of the claims must be interpreted in the broadest manner to comprise all obvious modifications and equivalent arrangements.

What is claimed is:

1. An antenna tuning switch structure, comprising:
an epitaxial substrate comprising a semiconductor substrate and a nitride heterostructure formed on the semiconductor substrate, wherein there is a two-dimensional electron gas within the nitride heterostructure;
a gate structure disposed on the nitride heterostructure; and
a source electrode and a drain electrode respectively arranged on opposite sides of the gate structure, wherein when the source electrode is connected to an antenna, the drain electrode is connected to a tuning element; when the drain electrode is connected to an antenna, the source electrode is connected to a tuning element; the gate structure is configured to control an electrical connection between the tuning element and the antenna.

2. The antenna tuning switch structure of claim 1, wherein the gate structure is a metal-insulator-semiconductor (MIS) structure, and the metal-insulator-semiconductor structure comprises a dielectric layer in contact with the nitride heterostructure and a gate electrode disposed on the dielectric layer.

3. The antenna tuning switch structure of claim 1, wherein the gate structure comprises a gallium nitride layer in contact with the nitride heterostructure and a gate electrode disposed on the gallium nitride layer, and a Schottky contact is formed between the gate electrode and the gallium nitride layer.

4. The antenna tuning switch structure of claim 1, wherein the gate structure is a P-type gallium nitride gate.

5. The antenna tuning switch structure of claim 1, wherein the nitride heterostructure comprises a buffer layer formed on the semiconductor substrate, a nitride channel layer formed on the buffer layer, and a Schottky layer formed on the nitride channel layer, and the two-dimensional electron gas is formed in the nitride channel layer near an interface between the nitride channel layer and the Schottky layer.

6. The antenna tuning switch structure of claim 5, wherein the buffer layer comprises an aluminum nitride/aluminum gallium nitride superlattice layer, an aluminum gallium nitride back barrier layer, an aluminum nitride back barrier layer and/or a graded/abrupt gallium nitride buffer layer.

7. The antenna tuning switch structure of claim 5, wherein a material of the nitride channel layer comprises gallium nitride, aluminum gallium nitride, indium aluminum nitride, aluminum nitride, scandium gallium nitride, scandium aluminum nitride, boron nitride, aluminum indium gallium nitride and/or indium gallium nitride.

8. The antenna tuning switch structure of claim 5, wherein a material of the Schottky layer comprises gallium nitride, aluminum gallium nitride, indium aluminum nitride, aluminum nitride, scandium gallium nitride, scandium aluminum nitride, boron nitride, aluminum indium gallium nitride and/or indium gallium nitride.

9. The antenna tuning switch structure of claim 1, wherein the semiconductor substrate is a substrate with a resistivity greater than 500 ohm-cm.

10. The antenna tuning switch structure of claim 9, wherein a material of the semiconductor substrate comprises floating zone silicon, gallium nitride, aluminum nitride, silicon carbide, sapphire or diamond.

11. The antenna tuning switch structure of claim 1, wherein a material of the semiconductor substrate comprises floating zone silicon, gallium nitride, aluminum nitride, silicon carbide, sapphire or diamond.

12. The antenna tuning switch structure of claim 1, wherein the source electrode and the drain electrode form ohmic contacts with the nitride heterostructure respectively.

13. The antenna tuning switch structure of claim 1, wherein the number of the gate structures is plural, and the source electrode and the drain electrode are respectively arranged on opposite sides of the plural gate structures.
